(19) United States
(12) Patent Application Publication
(10) Pub. No.: US 2020/0303299 A1
(43) Pub. Date: Sep. 24, 2020

(54) Semiconductor Device and Method of Manufacturing Semiconductor Device

(71) Applicant: TOSHIBA MEMORY CORPORATION, Tokyo (JP)

(72) Inventor: Yasuo TAKEMOTO, Kamakura Kanagawa (JP)

(73) Assignee: TOSHIBA MEMORY CORPORATION, Tokyo (JP)

(21) Appl. No.: 16/559,520

(22) Filed: Sep. 3, 2019

(30) Foreign Application Priority Data
Mar. 20, 2019 (JP) 2019-053678

(51) Int. Cl. H01L 23/522; H01L 25/18; H01L 25/00; H01L 23/00; H01L 21/768

(52) U.S. Cl. CPC H01L 23/5226; H01L 25/18; H01L 25/50; H01L 24/48; H01L 2224/49107; H01L 21/76877; H01L 21/76837; H01L 24/49; H01L 2924/1434; H01L 21/76802

(57) ABSTRACT

According to one embodiment, a semiconductor device includes a first wiring layer that includes a first surface and a second surface opposite to the first surface, a first semiconductor element that is mounted on the first surface side of the first wiring layer, a conductive pillar that is provided on the first surface side of the first wiring layer and has a height equal to or greater than a thickness of the first semiconductor element, a second wiring layer that includes a third surface and a fourth surface opposite to the third surface, is provided on the conductive pillar, and joined to the conductive pillar on the fourth surface side, a second semiconductor element that is mounted on the third surface side of the second wiring layer and connected to the second wiring layer by a first bonding wire, a first sealing material for sealing the first surface of the first wiring layer, the first semiconductor element, the conductive pillar, and the fourth surface of the second wiring layer, and a second sealing material for sealing the third surface of the second wiring layer, the second semiconductor element, and the first bonding wire.

### CROSS-REFERENCE TO RELATED APPLICATION(S)

This application is based upon and claims the benefit of priority from Japanese Patent Application No. 2019-053678, filed Mar. 20, 2019, the entire contents of which are incorporated herein by reference.

### FIELD

Embodiments described herein relate generally to a semiconductor device and a method of manufacturing the semiconductor device.

### BACKGROUND

Various package layouts have been studied in a semiconductor device using a nonvolatile memory chip. Semiconductor devices of nonvolatile memory are required to have characteristics such as increase in capacity, downsizing, and speeding up of reading and writing.

Examples of related art include JP-A-2018-514088.

### DESCRIPTION OF THE DRAWINGS

FIG. 1 is a cross-sectional view of a semiconductor device according to an embodiment;

FIG. 2 is a flowchart of a method of manufacturing the semiconductor device according to the embodiment;

FIG. 3 is a process diagram of the semiconductor device according to the embodiment;

FIG. 4 is a process diagram of the semiconductor device according to the embodiment;

FIG. 5 is a process diagram of the semiconductor device according to the embodiment;

FIG. 6 is a flowchart of a method of manufacturing the semiconductor device according to the embodiment;

FIG. 7 is a process diagram of the semiconductor device according to the embodiment;

FIG. 8 is a process diagram of the semiconductor device according to the embodiment;

FIG. 9 is a cross-sectional view of the semiconductor device according to the embodiment;

FIG. 10 is a cross-sectional view of the semiconductor device according to the embodiment; and

FIG. 11 is a cross-sectional view of the semiconductor device according to the embodiment.

### DETAILED DESCRIPTION

Embodiments provide a semiconductor device that contributes to the downsizing and thinning of semiconductor devices.

In general, according to one embodiment, a semiconductor device includes a first wiring layer including a first surface and a second surface, a first semiconductor feature on the first surface of the first wiring layer, a conductive pillar, provided on the first surface of the first wiring layer, that has a height equal to or greater than a thickness of the first semiconductor feature, a second wiring layer, joined to the conductive pillar, that includes a third surface and a fourth surface, a second semiconductor feature that is mounted on the third surface of the second wiring layer and connected to the second wiring layer by a first bonding wire, a first sealing material that seals the first surface of the first wiring layer, the first semiconductor feature, the conductive pillar, and the fourth surface of the second wiring layer, and a second sealing material that seals the third surface of the second wiring layer, the second semiconductor feature, and the first bonding wire.

Hereinafter, embodiments will be described with reference to drawings.

In the present specification, several elements are given examples of a plurality of expressions. The examples of these expressions are merely examples and do not deny that the above elements are expressed by other expressions. An element to which a plurality of expressions is not given may be expressed by another expression.

The drawings are schematic, and the relationship between thicknesses and planar dimensions, the proportion of the thickness of each layer, and the like may differ from actual ones. There may be portions where the dimensional relationships and proportions differ among the drawings.

### First Embodiment

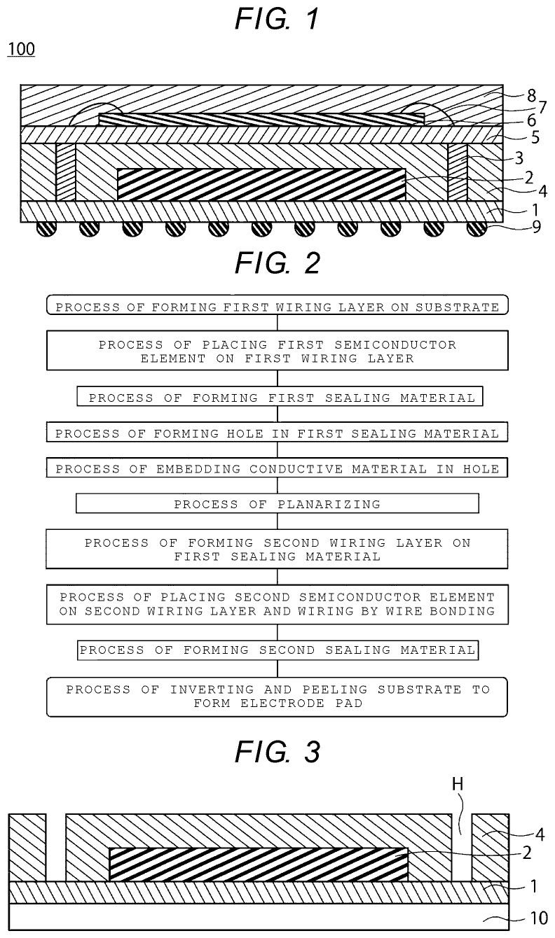

FIG. 1 illustrates a cross-sectional view of a semiconductor device 100 of an embodiment. The semiconductor device 100 is a semiconductor package. More specifically, in the semiconductor device 100, different types of semiconductor elements, for example, so-called ball grid array-solid state drives (BGA-SSD) are integrally configured as one BGA type package.

The semiconductor device 100 of FIG. 1 includes a first wiring layer 1, a first semiconductor element (or first semiconductor feature) 2, a conductive pillar 3, a first sealing material 4, a second wiring layer 5, a second semiconductor element (or second semiconductor feature) 6, a first bonding wire 7, a second sealing material 8, and electrode portions 9.

The first wiring layer 1 is provided in the semiconductor device 100 and holds the first semiconductor element 2 and the like. The first wiring layer 1 is a so-called rewiring layer. The first wiring layer 1 includes a wiring formed of a conductive member such as Cu in a resin layer. The first wiring layer 1 includes a first surface and a second surface opposite to the first surface. The first surface of the first wiring layer 1 is a surface on which the first semiconductor element 2 is mounted. The conductive pillar 3 is also formed on the first surface of the first wiring layer 1. Both the first semiconductor element 2 and the conductive pillar are directly connected to the wiring of the first wiring layer 1 and electrically connected. The first surface of the first wiring layer 1 is sealed with the sealing material 4. A pad portion connected to the conductive pillar 3 and a pad portion connected to the first semiconductor element 2 are provided on the first surface of the first wiring layer 1, and a plurality of electrode portions 9 formed of a hemispherical electrode are provided on the second surface. Each of the electrode portions 9 may be a flat electrode in the case of land grid array (LGA), or may be any of various types of electrode portions that can be electrically connected to the outside of the semiconductor device 100.

The first semiconductor element 2 is mounted on the first surface side of the first wiring layer 1. The first semiconductor element 2 is disposed between the first wiring layer 1 and the second wiring layer 5. The first semiconductor element 2 is a so-called flip chip, and the first semiconductor element 2 includes a bump electrode on the first surface side of the first wiring layer 1, and the bump electrode and the pad portion formed on the wiring of the first wiring layer 1 are connected. The first semiconductor element 2 is, for example, a controller (element) that controls the second semiconductor element 6.

The conductive pillar 3 is a wiring connecting the first wiring layer 1 and the second wiring layer 5. The conductive pillar 3 is disposed between the first wiring layer 3 and the second wiring layer 5 and is directly connected to both the first wiring layer 3 and the second wiring layer 5. As illustrated in FIG. 1, at least two or more conductive pillars 3 are provided in the semiconductor device 100, and the first semiconductor element 2 is located between the conductive pillars 3. The conductive pillar 3 is joined to the wiring on the first surface side of the first wiring layer 1 and is joined to a fourth surface of the second wiring layer 5. The conductive pillar 3 is made of, for example, a conductive metal such as Cu. The height of the conductive pillar 3 (the distance from the first wiring layer 1 to the second wiring layer 5) is equal to or greater than the thickness of the first semiconductor element. When the wiring of the first wiring layer 1 is made of Cu and the conductive pillar 3 is made of Cu, the Cu is joined to each other.

The first sealing material 4 seals the first surface of the first wiring layer 1, the first semiconductor element 2, the conductive pillar 3, and a fourth surface of the second wiring layer 5, which is a surface facing the first wiring layer 1. The first sealing material 4 is, for example, a mold resin.

The second wiring layer 5 is provided in the semiconductor device 100 and holds the second semiconductor element 6 and the like. The second wiring layer 5 is a so-called rewiring layer. The second wiring layer 5 connects the first semiconductor element 2 and the second semiconductor element 6 via the conductive pillar 3 and the first bonding wire 7. Similarly to the first wiring layer 1, the second wiring layer 5 also has a structure in which a wiring is formed in a resin layer. The second wiring layer 5 includes a third surface and a fourth surface opposite to the third surface. The second semiconductor element 6 is mounted on the third surface side of the second wiring layer 5. The fourth surface side of the second wiring layer 5 is joined to the conductive pillar 3.

By directly connecting the second wiring layer 5 and the conductive pillar 3 without using a solder ball or the like, the height can be reduced by the amount of a bonding member such as a solder ball. If separate sub-packages were manufactured on the first semiconductor element side and the second semiconductor element side, and then these sub-packages are joined, for example, a glass epoxy substrate is used for at least one of the sub-packages in view of strength. If an inorganic wiring substrate such as a glass epoxy substrate is not used for any of the sub-packages, the strength is insufficient when the sub-packages are manufactured or the strength is insufficient when the sub-packages are joined. Therefore, it is not practical to join sub-packages to obtain one package unless an inorganic wiring layer such as a glass epoxy substrate is used. Since the semiconductor device 100 of the embodiment is not obtained by joining the sub-packages, no gap is generated between the second wiring layer 5 and the first sealing material 4.

The first sealing material 4 covering the second wiring layer 5 and the first semiconductor element 2 is located to be aligned on one straight line in the stacking direction. The second sealing material for sealing the first wiring layer 1 and the second semiconductor element 5 is located to be aligned on one straight line in the stacking direction.

The second semiconductor element 6 is mounted on the third surface side of the second wiring layer 5. An electrode pad provided on the surface opposite to the surface facing the second wiring layer 5 of the second semiconductor element 6 is connected to the second wiring layer 5. The second semiconductor element 6 is located between the second wiring layer 5 and the second sealing material 8. The second semiconductor element 6 is fixed, for example, with an adhesive layer such as a die attach film provided on the second wiring layer 5. The second semiconductor element 6 and the second wiring layer 5 are connected with the first bonding wire 7. The second semiconductor element 6 is, for example, a memory element (or memory feature). Examples of the memory element include a nonvolatile memory element or a combination of a nonvolatile memory element and a volatile memory element. As the nonvolatile memory element, a NAND memory chip, a phase change memory chip, a resistance change memory chip, a ferroelectric memory chip, a magnetic memory chip or the like may be used. As the volatile memory element, a dynamic random-access memory (DRAM) chip or the like may be used.

The first bonding wire 7 is a wiring connecting the second wiring layer 5 and the second semiconductor element 6. The first bonding wire 7 is connected to the wiring of the second wiring layer 5. The first bonding wire 7 is a wire such as Au, for example.

The second sealing material 8 seals the third surface of the second wiring layer 5, the second semiconductor element 6, and the first bonding wire 7. The second sealing material 8 is, for example, a mold resin.

The electrode portion 9 is an electrode provided on the second surface side of the first wiring layer 1. The electrode portion 9 is, for example, a ball pad electrode.

Next, a method of manufacturing the semiconductor device 100 will be described. In the description of the manufacturing method, a process diagram is referred partially. The method of manufacturing the semiconductor device 100 includes a first process of providing the first wiring layer 1, the first semiconductor element 2, the conductive pillar 3, and the first sealing material 4 on a substrate, a second process of forming the second wiring layer 5, the second semiconductor element 6, the first bonding wire 7 and the second sealing member 8 on the first sealing member 4 after the first process, and a process of peeling a glass substrate after the second process to form the electrode portion 9 on the surface from which the substrate is peeled.

FIG. 2 illustrates a flowchart of a method of manufacturing the semiconductor device 100. The manufacturing method illustrated in the flowchart of FIG. 2 is an example of the manufacturing method of the semiconductor device 100. As illustrated in FIG. 2, more specifically, the method of manufacturing the semiconductor device 100 includes a process of forming the first wiring layer 1 on a substrate 10, a process of placing the first semiconductor element 2 on the first wiring layer 1, a process of forming the first sealing material 4, a process of forming a hole H in the first sealing material 4, a process of embedding a conductive material in the hole H (or filling the hole H with the conductive material), a process of planarizing, a process of forming the second wiring layer 5 on the first sealing material 4, a process of placing the second semiconductor element 6 on the second wiring layer 5 and wiring by wire bonding, a process of forming the second sealing material 8, a process of inverting and peeling off the substrate 10 to form the electrode portion 9.

First, the first wiring layer 1 is formed on the substrate 10. Wiring members are formed on the substrate 10 and patterned to form a resin layer. The resin layer is further patterned, a conductive member is further formed, and patterning is performed to obtain the first wiring layer 1. The material of the wiring member may be Al or Cu. Sputtering or plating may be used to form the wiring. A photosensitive polyimide or the like may be used for the resin layer. A pad portion connected to the first semiconductor element 2 and a pad portion connected to the conductive pillar 3 are formed in the first wiring layer 1. Then, the first semiconductor element 2 manufactured by another process is placed on the first surface of the first wiring layer 1, and the pad portion of the first wiring layer 1 and the bump electrode of the first semiconductor element 2 are connected with a flip chip. Then, the first surface of the first wiring layer 1 and the first semiconductor element 2 are sealed with the first sealing material 4, and the hole H is formed in the first sealing material 4 by laser processing or dry etching processing to obtain the members illustrated in the process diagram of FIG. 3.

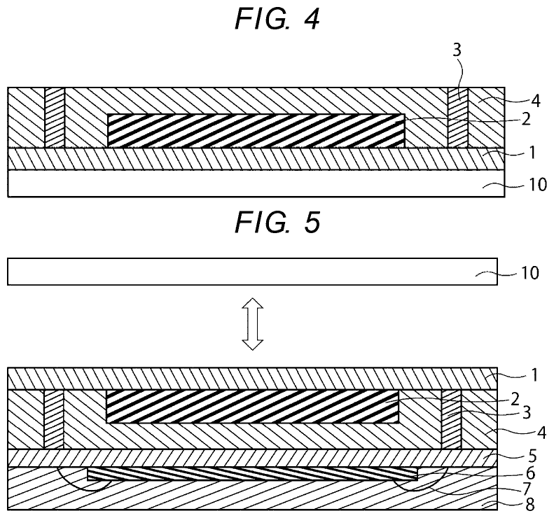

Then, a conductive material which is a material of the conductive pillar 3 is embedded in the hole H of the members illustrated in the process diagram of FIG. 3, and the conductive pillar 3 and the first sealing material 4 are planarized to obtain the members illustrated in the process diagram of FIG. 4. Here, the conductive pillar 3 may be formed by plating or by embedding a conductive material in the hole by screen printing, ink jet, or the like. After planarization, the conductive material in the hole H becomes the conductive pillar 3. A conductive material is embedded to electrically connect the conductive pillar 3 and the first wiring layer 1. More specifically, the wiring material of the first wiring layer 1 and the conductive pillar 3 are joined.

Even if there is no planarization, for example, the conductive pillar 3 may slightly protrude or may be recessed from the first sealing material 4 as long as the conductive pillars 3 and the wiring of the second wiring layer 5 are electrically connected in the subsequent process of forming the second wiring layer 5.

Then, the second wiring layer 5 is formed on the first sealing material 4 of the members illustrated in the process diagram of FIG. 4, and the conductive pillar 3 and the second wiring layer 5 are electrically connected. Wiring members are formed on the conductive pillars 3 and the first sealing material 4 and patterned to form a resin layer. The resin layer is further patterned, a conductive member is further formed, and patterning is performed to obtain the second wiring layer 5. The material of the wiring member may be Al or Cu. Sputtering or plating may be used to form the wiring. A photosensitive polyimide or the like may be used for the resin layer. A pad portion connected to a pad formed on the second semiconductor element 6 is formed on the third surface of the second wiring layer 5, and a pad portion connected to the conductive pillar 3 is formed on the fourth surface. Then, the second semiconductor element 6 is placed on the second wiring layer 5, and the pad portion of the second semiconductor element 6 and the pad portion of the second wiring layer 5 are connected with the first bonding wire 7. The second wiring layer 5 and the second semiconductor element 6 may be adhered with an adhesive film such as a die attach film or may be adhered with a liquid adhesive or the like.

Then, the third surface of the second wiring layer 5, the second semiconductor element 6, and the first bonding wire 7 are sealed with the second sealing material 8, and planarization process is optionally performed. Then, as illustrated in the process diagram of FIG. 5, the substrate 10 is peeled off. The members obtained before and after peeling off the substrate 10 may be inverted (e.g., flip). Then, the hemispherical electrode portions 9 are formed on the surface of the first wiring layer 1 from which the substrate 10 is peeled to obtain the semiconductor device 100 of FIG. 1.

The substrate 10 is not particularly limited as long as the substrate has sufficient strength in the above process, and a glass plate may typically be used. Silicon may be used as well. The first wiring layer 1 and the substrate 10 may be easily peeled off by applying a peeling agent on the substrate 10. Before forming the first wiring layer 1 on the substrate 10, a peeling layer with high light absorption may be formed. Here, the substrate 10 is, for example, light-permeable, and substrate 10 may be peeled by radiating laser light thorough the substrate 10 to thermally decompose the peeling layer.

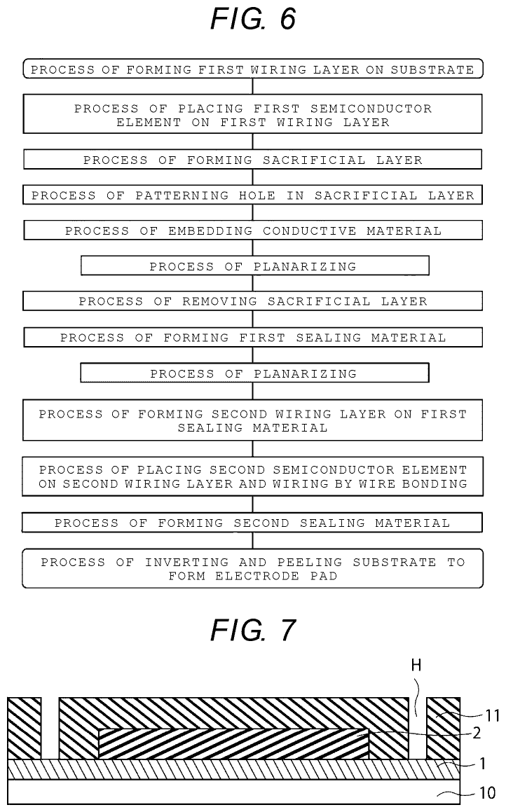

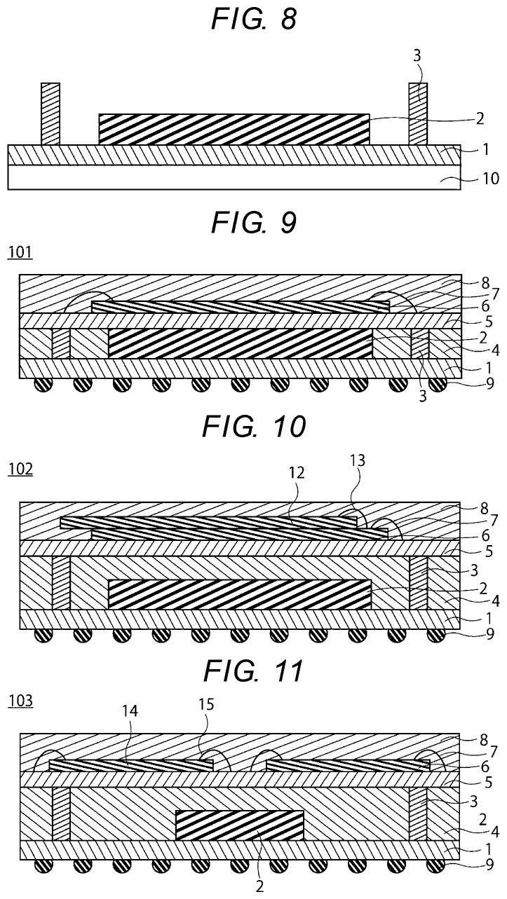

An example of another method of manufacturing the semiconductor device 100 will be described with reference to the flowchart of FIG. 6 and the process diagrams of FIGS. 7 and 8. As illustrated in FIG. 2, more specifically, the method of manufacturing the semiconductor device 100 includes a process of forming the first wiring layer 1 on the substrate 10, a process of placing the first semiconductor element 2 on the first wiring layer 1, a process of forming a sacrificial layer 11, a process of forming the hole H in the sacrificial layer 11, a process of embedding a conductive material in the hole H, a process of removing the sacrificial layer 11, a process of forming the first sealing material 4, a process of planarizing, a process of forming the second wiring layer 5 on the first sealing material 4, a process of placing the second semiconductor element 6 on the second wiring layer 5 and wiring by wire bonding, and a process of forming the second sealing material 8, inverting, and peeling the substrate 10 to form the electrode portion 9.

First, the first wiring layer 1 is formed on the substrate 10. Wiring members are formed on the substrate 10 and patterned to form a resin layer. The resin layer is further patterned, a conductive member is further formed, and patterning is performed to obtain the first wiring layer 1. Then, the first semiconductor element 2 manufactured by another process is placed on the first surface of the first wiring layer 1 to wire the first wiring layer 1 and the first semiconductor element 2. Then, the sacrificial layer 11 is formed. The hole H is formed in the sacrificial layer 11 by etching the sacrificial layer 11 or the like to obtain the members illustrated in the process diagram of FIG. 7.

Then, a conductive material which is a material of the conductive pillar 3 is embedded in the hole H of the members illustrated in the process diagram of FIG. 7. Then, the sacrificial layer 11 is removed to obtain the members illustrated in the process diagram of FIG. 8. Here, the conductive pillar 3 may be formed by plating or by embedding a conductive material in the hole by screen printing, ink jet, or the like.

Then, the first sealing material 4 is formed and planarized to obtain the members illustrated in the process diagram of FIG. 4. Thereafter, the semiconductor device 100 of FIG. 1 is obtained in the same manner as described above.

### Second Embodiment

A semiconductor device of a second embodiment is a modification example of the semiconductor device of the first embodiment. FIG. 9 illustrates a schematic cross-sectional view of a semiconductor device 101 of the second embodiment. In the semiconductor device 101 of FIG. 9, the surface of the first semiconductor element 2 is in contact with the fourth surface of the second wiring layer 5. In the semiconductor device 101 of the second embodiment, the thickness of the first sealing material 4 is thin, and the height of the conductive pillar 3 is low. The thickness of the first sealing material 4 is thin enough that the surface of the first semiconductor element 2 on the second wiring layer 5 is in contact with or contacts the second wiring layer 5. Except these things, the rest is common in the first embodiment and the second embodiment. The description of the contents common to the first embodiment and the second embodiment is omitted.

By thinning the first sealing material 4, the height of the semiconductor device 100 can be reduced. The size of the memory package tends to increase as the capacity of the memory device increases and the functionality of the controller element increases, but since the size of the package itself is also limited, it is possible to provide a semiconductor device satisfying the required functions while reducing the package size.

### Third Embodiment

A semiconductor device of a third embodiment is a modification example of the semiconductor device of the first embodiment. FIG. 10 illustrates a schematic cross-sectional view of a semiconductor device 102 of the third embodiment. The semiconductor device 102 of FIG. 10 includes one or more third semiconductor elements 12 mounted on the second semiconductor element 6. The second semiconductor element 6 and the third semiconductor element 12 are connected with a second bonding wire 13. Except these things, the rest is common in the first embodiment and the third embodiment. The description of the contents common to the first embodiment and the third embodiment is omitted.

Although one third semiconductor element 12 is provided on the second semiconductor element 6 in FIG. 10, two or more third semiconductor elements 12 may be further stacked. The second semiconductor element 6 and the third semiconductor element 12 are adhered with an adhesive layer such as a die attach film (not illustrated).

The third surface of the second wiring layer 5, the third semiconductor element 12, and the second bonding wire 13 are sealed with the second sealing material 8. The second semiconductor element 6 and the third semiconductor element 12 are preferably semiconductor elements having the same function. If the second semiconductor element 6 and the third semiconductor element 12 are, for example, memory elements, it is possible to obtain a large capacity memory chip while reducing the height of the package.

### Fourth Embodiment

A semiconductor device of a fourth embodiment is a modification example of the semiconductor device of the first embodiment. FIG. 11 illustrates a schematic cross-sectional view of a semiconductor device 103 of the fourth embodiment. The semiconductor device 103 of the fourth embodiment includes a fourth semiconductor element mounted on the third surface of the second wiring layer 5. The fourth semiconductor element 14 and the second wiring layer 5 are connected with a third bonding wire 15. The second semiconductor element 6 and the fourth semiconductor element 14 on the second wiring layer 5 are mounted side by side. The fourth semiconductor element and the third bonding wire 15 are also sealed with the second sealing material 8. Except these things, the rest is common in the first embodiment and the fourth embodiment. The description of the contents common to the first embodiment and the fourth embodiment is omitted.

The second semiconductor element 6 and the fourth semiconductor element 14 may be the same element or different elements. For example, a NAND memory may be used as the second semiconductor element 6, and a DRAM may be used as the fourth semiconductor element 15. Since a NAND is slower in reading and writing than a DRAM, using DRAM as a cache can speed up reading and writing of the semiconductor device 100. Both the second semiconductor element 6 and the fourth semiconductor element 14 can be stacked as in the semiconductor device 102 of the third embodiment, and such a structure is preferable from the viewpoint of increasing the capacity. For example, using a NAND memory for both the second semiconductor element 6 and the fourth semiconductor element 14 and writing in the second semiconductor element 6 and the fourth semiconductor element 14 alternately can improve the writing speed. In the semiconductor device 103 according to the fourth embodiment, the functions such as large capacity and high-speed read/write can be compatible while reducing the height of the package.

A plurality of modification examples of the method of manufacturing the semiconductor devices 100 to 103 of the embodiment will be described below. After the conductive pillar 3 is formed, the first surface of the first wiring layer 1, the first semiconductor element 2, and the conductive pillar 3 may be sealed with the first sealing material 4, and then planarized to obtain the members illustrated in the process diagram of FIG. 4. Here, the conductive pillars 3 may be formed by a known electrolytic plating method.

After forming a sacrificial layer pillar at a position where the conductive pillar 3 is to be formed, the first surface of the first wiring layer 1, the first semiconductor element 2, and the sacrificial layer pillar may be sealed with the first sealing material 4, and then planarized to dissolve the sacrificial layer and obtain the members illustrated in the process diagram of FIG. 3.

The members illustrated in FIGS. 3 and 4 can be obtained by various other methods.

The conductive pillars 3 may be formed by plating Ni, Au or the like other than Cu. The conductive pillars 3 may be formed by embedding various conductive pastes such as Ag paste.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a first wiring layer including a first surface and a second surface;
a first semiconductor feature on the first surface of the first wiring layer;
a conductive pillar, provided on the first surface of the first wiring layer, that has a height equal to or greater than a thickness of the first semiconductor feature;
a second wiring layer, joined to the conductive pillar, that includes a third surface and a fourth surface;
a second semiconductor feature that is mounted on the third surface of the second wiring layer and connected to the second wiring layer by a first bonding wire;
a first sealing material that seals the first surface of the first wiring layer, the first semiconductor feature, the conductive pillar, and the fourth surface of the second wiring layer; and
a second sealing material that seals the third surface of the second wiring layer, the second semiconductor feature, and the first bonding wire.

2. The semiconductor device according to claim 1, wherein
the second semiconductor feature is a memory device; and
the first semiconductor feature is a memory controller.

3. The semiconductor device according to claim 2, further comprising:
one or more third semiconductor features, which include memory features associated with the memory device, mounted on the second semiconductor feature, wherein
the second semiconductor feature and each of the one or more third semiconductor features are connected by a respective second bonding wire.

4. The semiconductor device according to claim 2, further comprising:
a fourth semiconductor feature mounted on the third surface of the second wiring layer, wherein
the fourth semiconductor feature and the second wiring layer are connected by a third bonding wire.

5. A method of manufacturing a semiconductor device, comprising:
providing a first wiring layer on a sacrificial substrate;
forming a first semiconductor feature, a conductive pillar, and a first sealing material on the first wiring layer;
forming a second wiring layer on the first sealing material;
forming a second semiconductor feature, a first bonding wire, and a second sealing material on the second wiring layer; and
separating the sacrificial substrate from the first wiring layer; and
forming an electrode portion on a surface of the first wiring layer from which the sacrificial substrate is separated.

6. The method according to claim 5, wherein the electrode portion includes a ball pad electrode.

7. The method according to claim 5, wherein forming a first semiconductor feature, a conductive pillar, and a first sealing material on the first wiring layer further comprises:
forming the first sealing material on the first wiring layer;
forming a hole extending through the first sealing material; and
filling the hole with a conductive material to form the conductive pillar.

8. The method according to claim 5, wherein forming a first semiconductor feature, a conductive pillar, and a first sealing material on the first wiring layer further comprises:
forming a sacrificial layer on the first wiring layer;
forming a hole extending through the sacrificial layer;
filling the hole with a conductive material to form the conductive pillar;
removing the sacrificial layer; and
forming the first sealing material over the first wiring layer.

9. The method according to claim 5, wherein
the first semiconductor feature is laterally separated from the conductive pillar on the first wiring layer.

10. The method according to claim 5, wherein the sacrificial substrate includes a glass substrate.
